(19) United States
(12) Patent Application Publication
(10) Pub. No.: US 2014/0351677 A1
(43) Pub. Date: Nov. 27, 2014

(54) MINIMUM CUT SET EVALUATION SYSTEM, MINIMUM CUT SET CALCULATION METHOD, AND PROGRAM

(71) Applicant: NEC Corporation, Minato-ku Tokyo (JP)

(72) Inventor: Jianwen Xiang, Tokyo (JP)

(73) Assignee: NEC CORPORATION, Minato-ku, Tokyo (JP)

(21) Appl. No.: 14/363,696

(22) PCT Filed: Dec. 7, 2012
(86) PCT No.: PCT/JP2012/081771

§ 371 Date: Jun. 6, 2014

(30) Foreign Application Priority Data
Dec. 9, 2011 (JP) 2011-270729

(51) Int. Cl. H03M 13/39

(52) U.S. Cl. CPC H03M 13/3961
USPC 714/796

(57) ABSTRACT

The present invention is a minimum cut set calculation system for calculating minimum cut sets of a fault tree with binary decision diagram (BDD), comprising: subtracting means for, from one of two sub-BDDs of an input BDD, removing redundant paths included in the other sub-BDD using a recursive function comprised of a recursive case and a base case, wherein said subtracting means comprises equivalence removing means for, when said two sub-BDDs are equivalent, outputting a terminal node 0 in said base case.

### TECHNICAL FIELD

The present invention relates to a minimum cut set evaluation system, a minimum cut set calculation method, and a program, and particularly to a minimum cut set evaluation system, a minimum cut set calculation method, and a program for calculating minimum cut sets (MCSs) of a fault tree with binary decision diagram (BDD).

### BACKGROUND ART

NPLs 1 and 2 disclose technologies related to the present invention. A conventional algorithm disclosed in NPL 1 is shown in FIGS. 1 and 2.

The conventional algorithm shown in FIGS. 1 and 2 is comprised of two recursive functions named as “minsol” and “without.” These are for calculating the minimal solutions for a given binary decision diagram (abbreviated as BDD hereinbelow), and removing redundant paths included in another BDD from the BDD.

Although the conventional algorithm is considered as a typical technique for calculating minimum cut sets (MCSs) in a fault tree with BDDs, it still has problems, as described below.

First, as shown in FIG. 2, the function “without” only takes account of the base case when one of two input BDDs (F and G) is a terminal node 1 or terminal node 0, and does not take account of the base case when the two input BDDs are not terminal nodes and are the same node, that is, when

F=G [symbol] F,G ∉{0,1}.

In such a case, F and G, which are the two input BDDs, must be recursively decomposed and evaluated by the function “without,” regardless of whether they are equivalent or not (see ‘x=y’ for the last ‘else’ in FIG. 2). The recursive decomposition and evaluation in this case is obviously unnecessary because F=G.

The omission of the base case of F=G (F, G ∉{0,1}) could result from that a reduced BDD includes no useless node within the form of ite(x, F, F) (“ite” denotes decomposition by if-then-else).

However, without(F, F) is often applied due to the presence of shared nodes in a BDD, even if no useless node is found in the BDD.

Second, as shown in FIG. 1, the function “without” is called in the process of minimization of F after minimization (calculation of a minimal solution) of G, which is a sub-BDD of F. In addition, as presented in Theorem 10 in NPL 2, there is proposed a modification in which the function “without” is called in the process of minimization of an original BDD after two sub-BDDs have been minimized. As such, according to the technologies in NPLs, the function “without” is not called before the two sub-BDDs are minimized.

### CITATION LIST

### Non Patent Literature

NPL 1: A. Rauzy: “New algorithms for fault trees analysis,” Reliability Engineering and System Safety, 40 (3), Elsevier, 1993, pp. 203-211.

NPL 2: Y. Dutuit and A. Rauzy: “Exact and Truncated Computations of Prime Implicants of Coherent and Non-Coherent Fault Trees with Aralia,” Reliability Engineering and System Safety, 58 (2), Elsevier, 1997, pp. 127-144.

### SUMMARY OF INVENTION

### Technical Problem

The aforementioned technologies have the following problems.

The first problem is that the technologies in the above-described NPLs recursively apply unnecessary processing of removing redundant paths to two equivalent BDDs. A reason thereof is that the conventional algorithms do not consider the base case that the two input BDDs of the “without” function could be the same.

The second problem is that a method that processes the function “without” afterward, as in the technologies in the above-described NPLs, lowers the efficiency of minimization. Performance of minimization of a BDD is generally dependent upon the size of sub-BDDs of the BDD. When a BDD is established, minimization of the two sub-BDDs of the BDD is sometimes inefficient, because the load of the processing of minimization of sub-BDDs would increase by proceeding to the processing without removing beforehand redundant paths from one sub-BDD that are included in paths of the other sub-BDD, as in the algorithms in the above-described NPLs.

The present invention has thus been made in view of such problems, and its objective is to provide a technology for calculating minimum cut sets of a fault tree from a binary decision diagram (BDD) in a more efficient way.

### DISCLOSURE OF THE INVENTION

The present invention is a minimum cut set calculation system for calculating minimum cut sets of a fault tree with binary decision diagram (BDD), comprising: subtracting means for, from one of two sub-BDDs of an input BDD, removing redundant paths included in the other sub-BDD using a recursive function comprised of a recursive case and a base case, wherein said subtracting means comprises equivalence removing means for, when said two sub-BDDs are not terminal nodes and are equivalent, outputting a terminal node 0 in said base case.

The present invention is a minimum cut set calculation system for calculating minimum cut sets of a fault tree with binary decision diagram (BDD), comprising: minimizing means for calculating minimum cut sets of a fault tree with BDD using a recursive function comprised of a recursive case and a base case, wherein said minimizing means performs a calculation of said recursive case after redundant paths in a sub-BDD of said BDD have been removed.

The present invention is a minimum cut set calculation method for calculating minimum cut sets of a fault tree with binary decision diagram (BDD), comprising: subtracting processing of, from one of two sub-BDDs of an input BDD, removing redundant paths included in the other sub-BDD using a recursive function comprised of a recursive case and a base case, wherein said subtracting processing comprises equivalence removing processing of outputting a terminal node 0 when said two sub-BDDs are not terminal nodes and are equivalent in said base case.

The present invention is a minimum cut set calculation method for calculating minimum cut sets of a fault tree with binary decision diagram (BDD), comprising: minimizing processing of calculating minimum cut sets of a fault tree with BDD using a recursive function comprised of a recursive case and a base case, wherein said minimizing processing performs a calculation of said recursive case after redundant paths in a sub-BDD of said BDD have been removed.

The present invention is a minimum cut set calculation program for calculating minimum cut sets of a fault tree with binary decision diagram (BDD), said minimum cut set calculation program causing a computer to execute: subtracting processing of, from one of two sub-BDDs of an input BDD, removing redundant paths included in the other sub-BDD using a recursive function comprised of a recursive case and a base case, wherein said subtracting processing comprises equivalence removing processing of outputting a terminal node 0 when said two sub-BDDs are not terminal nodes and are equivalent in said base case.

The present invention is a minimum cut set calculation program for calculating minimum cut sets of a fault tree with binary decision diagram (BDD), said minimum cut set calculation program causing a computer to execute: minimizing processing of calculating minimum cut sets of a fault tree with BDD using a recursive function comprised of a recursive case and a base case, wherein said minimizing processing performs a calculation of said recursive case after redundant paths in a sub-BDD of said BDD have been removed.

### ADVANTAGEOUS EFFECTS OF INVENTION

According to the present invention, the minimum cut sets of a fault tree can be calculated from a binary decision diagram (BDD) encoding the fault tree by an effective method.

### BRIEF DESCRIPTION OF DRAWINGS

FIG. 1 is a diagram showing a “minsol” function according to NPL 1.

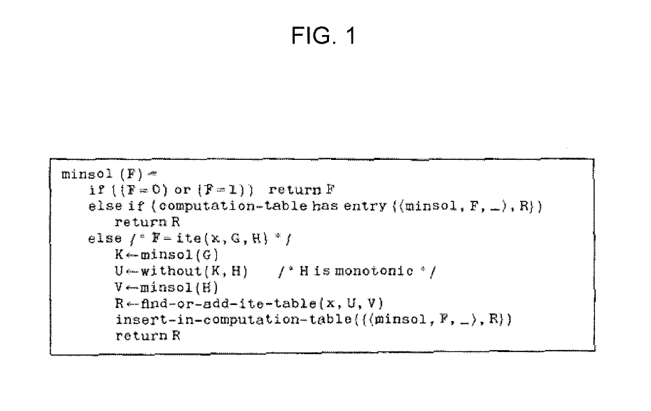

FIG. 2 is a diagram showing a “without” function according to NPL 1.

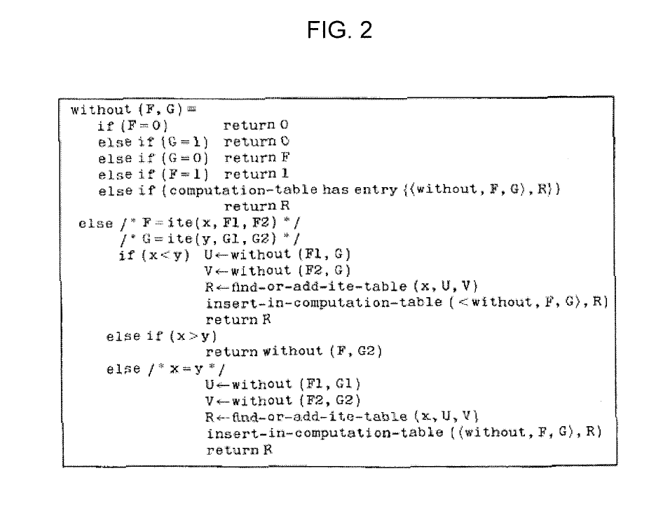

FIG. 3 is a block diagram showing a configuration of an embodiment of the present invention.

FIG. 4 is an operational flow chart of the embodiment of the present invention.

FIG. 5 is an operational flow chart of the embodiment of the present invention.

FIG. 6 is a diagram showing a “minsol” function.

FIG. 7 is a diagram showing a “without” function.

FIG. 8 is a diagram showing another “without” function.

FIG. 9 is a diagram showing a BDD in Example.

FIG. 10 is a diagram showing the BDD shown in FIG. 9 after without (3, 2) has been applied thereto.

FIG. 11 is a diagram showing a result of comparison between the numbers of calls to the functions according to the present invention and those according to a conventional technique.

FIG. 12 is a diagram showing a result of comparison for a benchmark fault tree between a case in which the present invention is applied and that in which the conventional technique is applied.

### DESCRIPTION OF EMBODIMENTS

Next, an embodiment of the present invention will be described in detail with reference to the accompanying drawings.

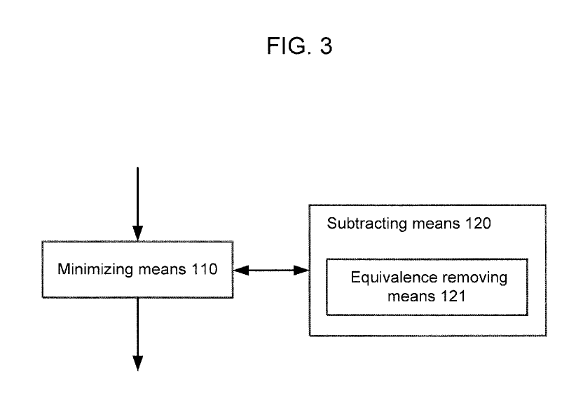

An embodiment of the present invention referred to in FIG. 3 comprises minimizing means 110 and subtracting means 120. The subtracting means 120 comprises equivalence removing means 121.

These means each operate generally as follows:

The minimizing means 110 is for calculating minimum cut sets (MCSs) of a given BDD. In a case the BDD is not a terminal node, i.e., it consists of two sub-BDDs, the minimizing means 110 calls the subtracting means 120 for removing from one sub-BDD all redundant paths included in paths of the other sub-BDD.

Given two sub-BDDs, the subtracting means 120 removes from one sub-BDD all redundant paths included in paths of the other sub-BDD.

The equivalence removing means 121 checks whether two BDDs input to the subtracting means 120 are equivalent or not, and in a case that the two BDDs are equivalent, it outputs a 0 (false) terminal node. That is, in a case that the first BDD and second BDD are equivalent, all paths in the first BDD are included in the second BDD, and a 0 (false) terminal node is output as a result.

In the configuration described above, the minimizing means 110 calls the subtracting means 120 before the processing of minimization is recursively applied to the two sub-BDDs of the input BDD. After redundant paths have been removed by the subtracting means 120, the recursive calculation of minimization of the two sub-BDDs is performed.

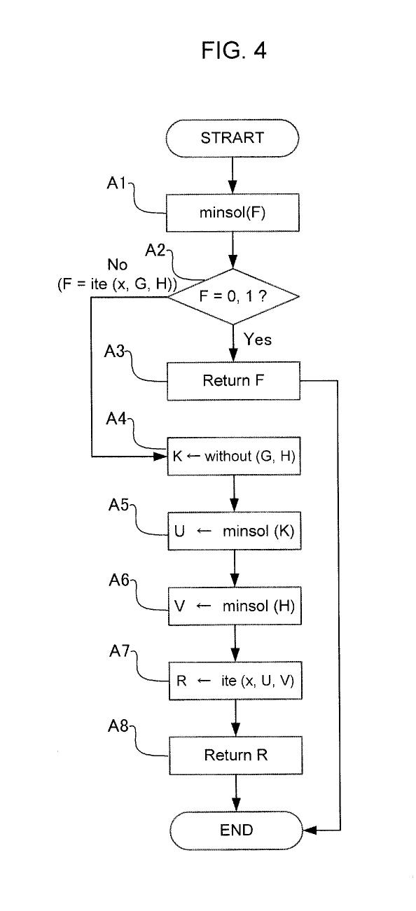

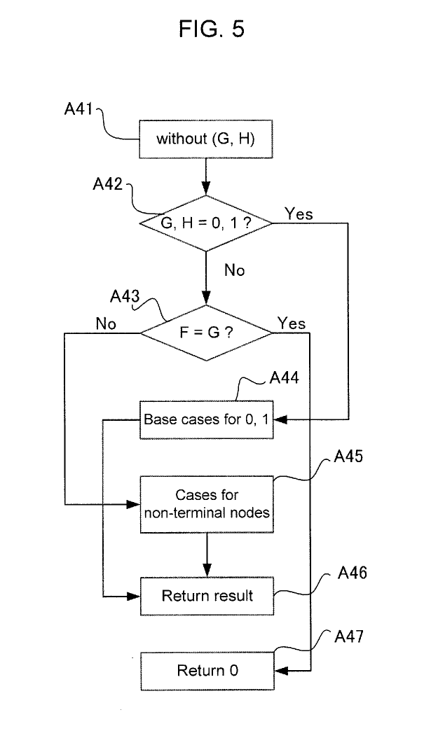

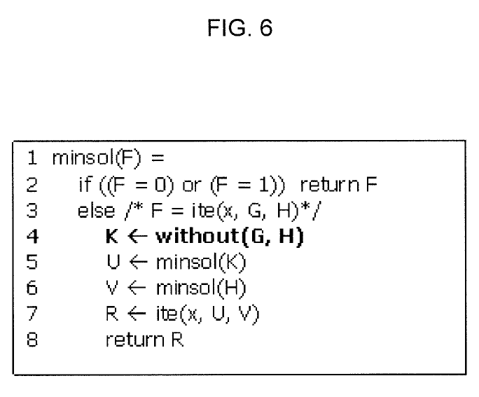

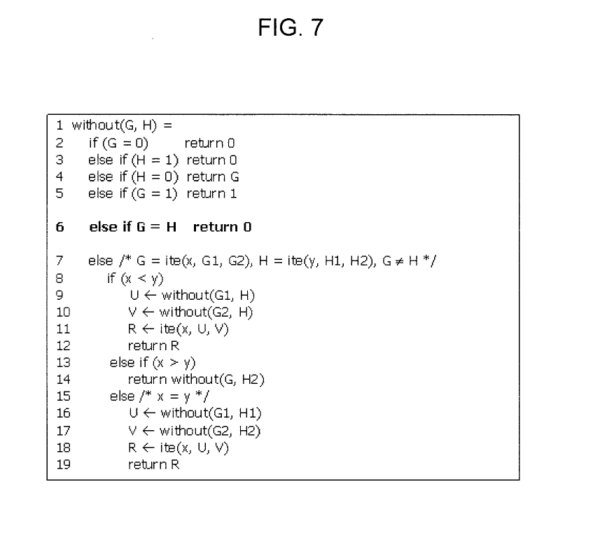

Next, a general operation of the present embodiment will be described in detail with reference to FIG. 3, the flow charts in FIGS. 4 and 5, a function “minsol” shown in FIG. 6, and a function “without” shown in FIG. 7.

First, one BDD (denoted as BDD_F hereinbelow) is input to the system (Step A1), and processed by the minimizing means 110. To compare the algorithm with that in NPL 1, the same name “minsol” is used herein, which is defined as a function for use by the minimizing means 110.

The minimizing means 110 checks whether BDD_F is a terminal node (0-terminal or 1-terminal) (Step A2). In a case that BDD_F is a terminal node (Step A2: Yes), BDD_F itself is returned (Step A3). In a case that BDD_F is not a terminal node, and takes the form of F=ite(x, G, H) (where x is a Boolean variable, G is a sub-BDD (node) of BDD_F that is connected by a 1-edge, and H is a sub-BDD (node) of BDD_F that is connected by a 0-edge) (Step A2: No), the function without(G, H) is called by the subtracting means 120, and a returned value therefrom is given as an intermediate variable K (Step A4). It should be noted that the function “without” is used by the subtracting means 120 for removing all paths that are included in paths in sub-BDD_H from sub-BDD G.

After redundant paths have been removed by the function “without,” the function minsol(K) is recursively called, and a returned value therefrom is saved as an intermediate variable U (Step A5).

A recursive call to the function minsol(H) is made for sub-BDD_H connected by a 0-edge of BDD_F, and a returned value therefrom is saved as an intermediate variable V (Step A6). Finally, as needed (for example, in a case that storage of the function “ite” is to be performed as proposed in NPLs 1 and 2), a new BDD ite(x, U, V) is generated from the saved intermediate variables U, V (Step A7), and output as R (Step A8).

Subsequently, the processing at Step A4 performed by the subtracting means 120 will be described using the flow chart in FIG. 5.

To perform the function without(G, H) (Step A41), the subtracting means 120 checks whether sub-BDD_G and/or sub-BDD_H are terminal nodes (0-terminal or 1-terminal) or not (Step A42). In a case that sub-BDD_G and/or sub-BDD_H are terminal nodes (0-terminal or 1-terminal) (Step A42: Yes), a base case (recited in lines 2 through 6 in FIG. 7) that makes no recursive call for a terminal node (0-terminal or 1-terminal) is applied (Step A44), and a result is output (Step A46).

In a case that sub-BDD_G and/or sub-BDD_H are not terminal nodes (0-terminal or 1-terminal) (Step A42: No), the equivalence removing means 121 in the subtracting means 120 checks whether sub-BDD_G and sub-BDD_H are equivalent (a non-terminal node BDD) (Step A43).

In a case that sub-BDD_G and sub-BDD_H are equivalent (Step A43: Yes), no recursive calculation of the function “without” is performed and zero is output as a result (Step A47). On the other hand, in a case that sub-BDD_G and sub-BDD_H are not equivalent (Step A43: No), a recursive case for not being a terminal node (recited in lines 7 through 18 in FIG. 7) is applied (Step A45), and a result thereof is output (Step A46).

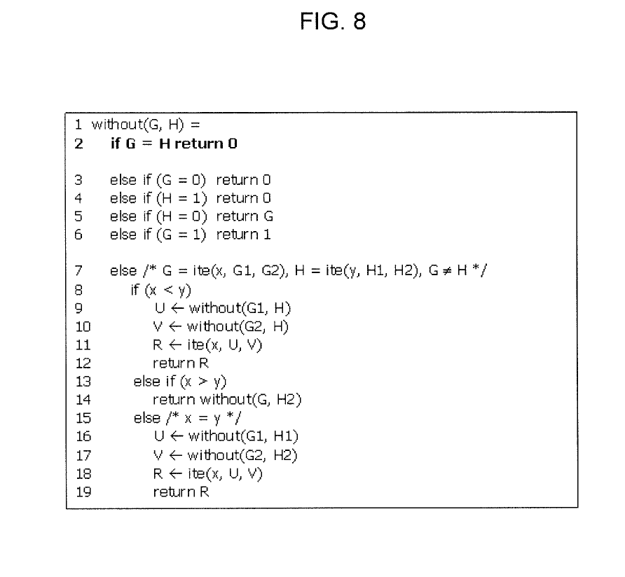

It should be noted that the check as to whether sub-BDD_G and sub-BDD_H are equivalent may be performed before the check as to whether sub-BDD_G and/or sub-BDD_H are terminal nodes. Variables corresponding to the function “without” for use by the subtracting means 120 in that case are shown in FIG. 8.

Next, an advantage of the present embodiment will be described.

The first advantage is that redundant paths between two equivalent BDDs can be removed without performing recursive processing. This is because all paths in the first BDD are included in the second BDD when the two BDDs are equivalent, and the equivalence removing means in the subtracting means outputs a 0 (false) terminal node as a result.

The second advantage is that the efficiency of the calculation of minimum cut sets (MCSs) can be increased as a whole. This is because the size and complexity of a sub-BDD are reduced by removing redundant paths before minimization of the sub-BDD, thus reducing cost of minimization of the sub-BDD.

Next, an operation of the present invention will be described using a specific example.

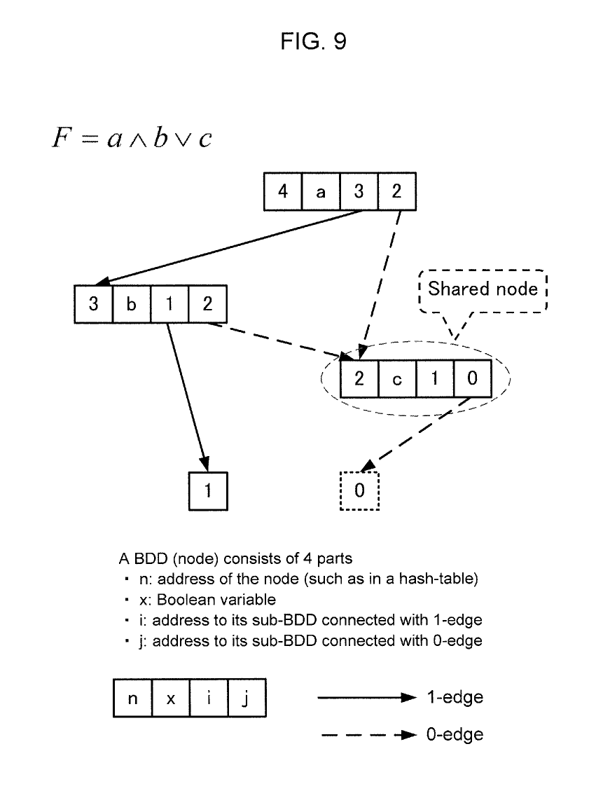

FIG. 9 shows an exemplary BDD.

A logical formula of the BDD shown in FIG. 9 is:

F=a [symbol] b [symbol] c.

Here, for brevity of description, a natural number is used for an address of each BDD node, and a 1-edge is indicated by a solid arrow and a 0-edge by a dotted arrow. The order of variables of BDD_F for decomposition/construction is defined as a<b<c.

The BDD shown in FIG. 9 has two shared terminal nodes (0-terminal and 1-terminal), and in addition, three BDD nodes. BDD nodes except the terminal nodes are each composed of four parts n, x, i, and j, where n denotes an address in a hash table, for example, x denotes a Boolean variable, i denotes an address of a sub-BDD (node) connected via a 1-edge, and j denotes an address of a sub-BDD (node) connected via a 0-edge. A node of address 4 can be represented as ite(a, 3, 2), and that of address 3 as ite(b, 1, 2), and that of address 2 as ite(c, 1, 0).

The node ite(c, 1, 0) of address 2 is a node shared by two parent nodes ite(a, 3, 2) and ite(b, 1, 2).

The minimizing means 110 calculates a minimum cut set (solution) of a BDD by the function minsol (4) (Step A1 in FIG. 4). In this example, a check is made as to whether an input parameter 4 (=F) is a terminal node (0-terminal or 1-terminal) (Step A2 in FIG. 4). Here, F=4 is not a terminal node. Then, to remove redundant paths between the sub-BDD node of address 3 and sub-BDD node of address 2, which are the sub-BDD nodes of address 4, the function without (3, 2) is called (Step A4 in FIG. 4 and Step A41 in FIG. 5).

Since the sub-BDD node of address 3 and sub-BDD node of address 2 are not terminal nodes (Step A42: No), and they are not equivalent (Step A43: No), two recursive functions without (1, 2) and without (2, 2) are called based on a case of x<y recited in lines 8 through 12 in FIG. 7 (Step A45 in FIG. 5).

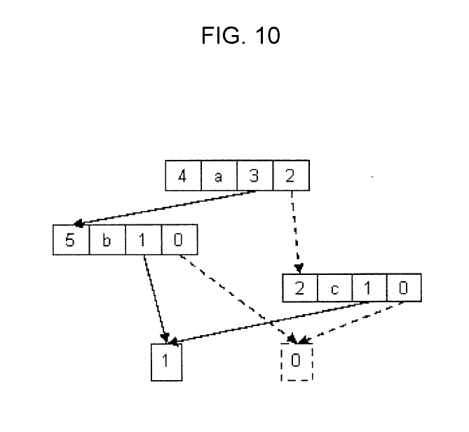

As recited in line 6 in FIG. 7, the function without (1, 2) returns 1 as a result. The function without (2, 2) returns 0 as a result. According to the results from the functions without (1, 2) and without (2, 2), a new BDD node ite (b, 1, 0) of address 5 is generated. The new BDD node is output as a result of the function without (3, 2) (Step A46 in FIG. 5). A modified BDD after the processing by the function without (3, 2) is shown in FIG. 10.

Minsol (5) and minsol (2) executed based on the BDD shown in FIG. 10 are similarly simple, and a finally output BDD having only a minimal solution is the same as that shown in FIG. 10. This is because it is not changed after minsol(5) and minsol(2).

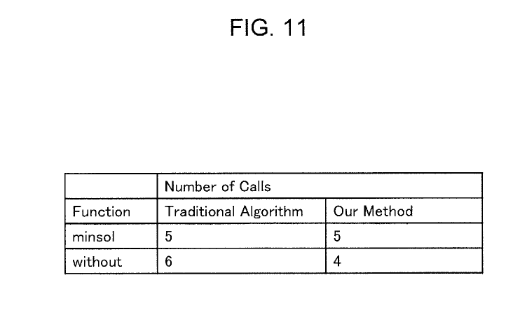

To clarify differences between the present invention and the conventional algorithm disclosed in NPL 1, statistic data of the numbers of calls to the two functions “minsol” and “without” by these two algorithms are shown in FIG. 11.

These values are obtained by implementing the two algorithms in Python, which is one programming language. According to the method of the present invention, the number of calls to the “without” function is reduced from 6 to 4, by 30%, in this example.

Moreover, the efficiency of the present invention is demonstrated according to an exemplary fault tree described in NPL 1.

The name of the fault tree is European 1, which is included in Appendix of NPL 1. The fault tree is comprised of 61 basic events (variables) and 84 gates (connectives), and has a size of 145 (the total number of the basic events and gates). It should be noted that there are two errors in the description of the reference. Specifically, gate g118 and gate g117 should be g118 :=(g114|c047) and g117 :=(g113|c046), respectively, not g118 :=(g114|g047) and g117 :=(g113|g 046).

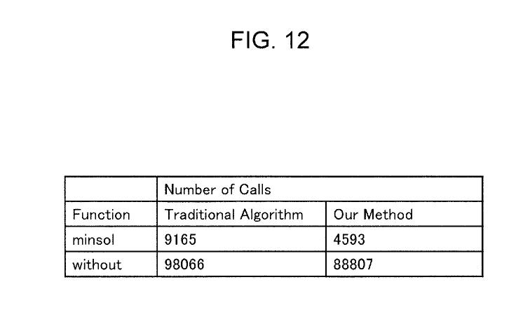

Statistic data for comparison of the conventional algorithm with the method of the present invention by the numbers of calls to the functions are shown in FIG. 12.

In this example, both the methods employ depth-first ordering, that is, a method of numbering basic events in the order of occurrence, for constructing equivalent BDDs.

It should be noted that the size of the BDD is 9165, which is different from that having a size of 6044 disclosed in NPL 1. A reason thereof is that although the ordering method is referred to as depth-first search in NPL 1, the ordering method and that of the present invention may possibly have some difference. Since the ordering method is not particularly described in NPL 1, we cannot correctly demonstrate differences between these ordering methods here.

The BDD constructed by the ordering method according to the present invention had 2202 shared nodes. This implies that a BDD may have a significant number of shared nodes. This very fact means that the method according to the present invention is able to process such shared nodes more efficiently. As shown in FIG. 12, the number of calls to the two functions “minsol” and “without” can be reduced by 15%, and further, the efficiency of the method according to the present invention is demonstrated for the fault tree that serves as a practical benchmark.

Now this is the end of the description of the embodiment, wherein while several components may be configured in hardware, they also may be implemented by a computer program, as is obvious from the preceding description. In this case, a processor that is operated by programs stored in a program memory implements functions and/or operations similar to those in the embodiment or example described above. It is also possible to implement part of functions of the embodiment or example described above by a computer program.

The embodiment described above may be also expressed as in the following appendices:

(Supplementary note 1) A minimum cut set calculation system for calculating minimum cut sets of a fault tree with binary decision diagram (BDD), comprising:

subtracting means for, from one of two sub-BDDs of an input BDD, removing redundant paths included in the other sub-BDD using a recursive function comprised of a recursive case and a base case, wherein

said subtracting means comprises equivalence removing means for, when said two sub-BDDs are not terminal nodes and are equivalent, outputting a terminal node 0 in said base case.

(Supplementary note 2) The minimum cut set calculation system according to Supplementary note 1, wherein:

said subtracting means removes redundant paths using said recursive case after a decision as to whether said two sub-BDDs are terminal nodes and a decision as to whether said two sub-BDDs are equivalent.

(Supplementary note 3) The minimum cut set calculation system according to Supplementary notes 1 or 2, comprising:

minimizing means for calculating minimum cut sets of a fault tree with BDD using a recursive function comprised of a recursive case and a base case, wherein

said minimizing means minimizes a sub-BDD by performing a calculation of said recursive case after redundant paths in said sub-BDD have been removed by said subtracting means.

(Supplementary note 4) A minimum cut set calculation system for calculating minimum cut sets of a fault tree with binary decision diagram (BDD), comprising:

minimizing means for calculating a minimum cut set of a fault tree comprised of a BDD using a recursive function comprised of a recursive case and a base case, wherein

said minimizing means performs a calculation of said recursive case after redundant paths in a sub-BDD of said BDD have been removed.

(Supplementary note 5) A minimum cut set calculation method for calculating minimum cut sets of a fault tree with binary decision diagram (BDD), comprising: subtracting processing of, from one of two sub-BDDs of an input BDD, removing redundant paths included in the other sub-BDD using a recursive function comprised of a recursive case and a base case, wherein

said subtracting processing comprises equivalence removing processing of outputting a terminal node 0 when said two sub-BDDs are not terminal nodes and are equivalent in said base case.

(Supplementary note 6) The minimum cut set calculation method according to Supplementary note 5, wherein:

said subtracting processing removes redundant paths using said recursive case after a decision as to whether said two sub-BDDs are terminal nodes and a decision as to whether said two sub-BDDs are equivalent.

(Supplementary note 7) The minimum cut set calculation method according to Supplementary notes 5 or 6, comprising:

minimizing processing of calculating minimum cut sets of a fault tree with BDD using a recursive function comprised of a recursive case and a base case, wherein

said minimizing processing minimizes a sub-BDD by performing a calculation of said recursive case after redundant paths in said sub-BDD have been removed by said subtracting processing.

(Supplementary note 8) A minimum cut set calculation method for calculating minimum cut sets of a fault tree with binary decision diagram (BDD), comprising:

minimizing processing of calculating a minimum cut set of a fault tree comprised of a BDD using a recursive function comprised of a recursive case and a base case, wherein

said minimizing processing performs a calculation of said recursive case after redundant paths in a sub-BDD of said BDD have been removed.

(Supplementary note 10) A minimum cut set calculation program for calculating minimum cut sets of a fault tree with binary decision diagram (BDD), said minimum cut set calculation program causing a computer to execute:

subtracting processing of, from one of two sub-BDDs of an input BDD, removing redundant paths included in the other sub-BDD using a recursive function comprised of a recursive case and a base case, wherein

said subtracting processing comprises equivalence removing processing of outputting a terminal node 0 when said two sub-BDDs are not terminal nodes and are equivalent in said base case.

(Supplementary note 11) A minimum cut set calculation program for calculating minimum cut sets of a fault tree with binary decision diagram (BDD), said minimum cut set calculation program causing a computer to execute:

minimizing processing of calculating minimum cut sets of a fault tree with BDD using a recursive function comprised of a recursive case and a base case, wherein

said minimizing processing performs a calculation of said recursive case after redundant paths in a sub-BDD of said BDD have been removed.

While the present invention has been described with reference to a preferred embodiment and an example, the present invention is not necessarily limited to the embodiment and example described above, and may be practiced with several modifications within a scope of the technical idea thereof.

The present application claims priority based on Japanese Patent Application No. 2011-270729 filed on Dec. 9, 2011, disclosure of which is incorporated herein in its entirety.

### REFERENCE SIGNS LIST

110 Minimizing means

120 Subtracting means

121 Equivalence removing means

1. A minimum cut set calculation system for calculating minimum cut sets of a fault tree with binary decision diagram (BDD), comprising:
subtracting means configured to, from one of two sub-BDDs of an input BDD, remove redundant paths included in the other sub-BDD using a recursive function comprised of a recursive case and a base case, wherein
said subtracting means comprises equivalence removing means configured to, when said two sub-BDDs are equivalent, output a terminal node 0 (false) in said base case.

2. The minimum cut set calculation system according to claim 1, wherein:
said subtracting means removes redundant paths using said recursive case after a decision as to whether said two sub-BDDs are terminal nodes and a decision as to whether said two sub-BDDs are equivalent.

3. The minimum cut set calculation system according to claim 1, comprising:
minimizing means configured to calculate minimum cut sets of a fault tree with BDD using a recursive function comprised of a recursive case and a base case, wherein
said minimizing means minimizes a sub-BDD by performing a calculation of said recursive case after redundant paths in said sub-BDD have been removed by said subtracting means.

4. A minimum cut set calculation system for calculating minimum cut sets of a fault tree with binary decision diagram (BDD), comprising:
minimizing means configured to calculate a minimum cut set of a fault tree comprised of a BDD using a recursive function comprised of a recursive case and a base case, wherein
said minimizing means performs a calculation of said recursive case after redundant paths in a sub-BDD of said BDD have been removed.

5. A minimum cut set calculation method for calculating minimum cut sets of a fault tree with binary decision diagram (BDD), comprising:
subtracting processing of, from one of two sub-BDDs of an input BDD, removing redundant paths included in the other sub-BDD using a recursive function comprised of a recursive case and a base case, wherein
said subtracting processing comprises equivalence removing processing of outputting a terminal node 0 (false) when said two sub-BDDs are equivalent in said base case.

6. The minimum cut set calculation method according to claim 5, wherein:
said subtracting processing removes redundant paths using said recursive case after a decision as to whether said two sub-BDDs are terminal nodes and a decision as to whether said two sub-BDDs are equivalent.

7. The minimum cut set calculation method according to claim 5, comprising:
minimizing processing of calculating minimum cut sets of a fault tree with BDD using a recursive function comprised of a recursive case and a base case, wherein
said minimizing processing minimizes a sub-BDD by performing a calculation of said recursive case after redundant paths in said sub-BDD have been removed by said subtracting processing.

8. A minimum cut set calculation method for calculating a minimum cut set of a fault tree comprised of a binary decision diagram (BDD), comprising:
minimizing processing of calculating minimum cut sets of a fault tree with BDD using a recursive function comprised of a recursive case and a base case, wherein
said minimizing processing performs a calculation of said recursive case after redundant paths in a sub-BDD of said BDD have been removed.

9. A non-transitory computer readable storage medium storing a minimum cut set calculation program for calculating minimum cut sets of a fault tree with binary decision diagram (BDD), said minimum cut set calculation program causing a computer to execute:
subtracting processing of, from one of two sub-BDDs of an input BDD, removing redundant paths included in the other sub-BDD using a recursive function comprised of a recursive case and a base case, wherein
said subtracting processing comprises equivalence removing processing of outputting a terminal node 0 (false) when said two sub-BDDs are not terminal nodes and are equivalent in said base case.

10. A non-transitory computer readable storage medium storing a minimum cut set calculation program for calculating minimum cut sets of a fault tree with binary decision diagram (BDD), said minimum cut set calculation program causing a computer to execute:
minimizing processing of calculating a minimum cut set of a fault tree comprised of a BDD using a recursive function comprised of a recursive case and a base case, wherein
said minimizing processing performs a calculation of said recursive case after redundant paths in a sub-BDD of said BDD have been removed.
